(19) United States
(12) Patent Application Publication
(10) Pub. No.: US 2011/0222571 A1
(43) Pub. Date: Sep. 15, 2011

(54) IMPROVEMENTS IN SEMICONDUCTOR LASERS

(75) Inventors: John Haig Marsh, Glasgow (GB); Stewart Duncan McDougall, Lanark (GB); Gianluca Bacchin, Glasgow (GB); Bocang Qiu, Glasgow (GB)

(73) Assignee: INTENSE LIMITED, Glasgow (GB)

(21) Appl. No.: 13/063,101

(22) PCT Filed: Sep. 11, 2009
(86) PCT No.: PCT/GB09/02187

§ 371 Date: May 13, 2011

(30) Foreign Application Priority Data
Sep. 11, 2008 (GB) 0816625.8
Oct. 2, 2008 (GB) 0818020.0

(51) Int. Cl. H01S 5/40; F21V 5/00; B41J 2/45

(52) U.S. Cl. 372/50.122; 362/235; 372/50.12

(57) ABSTRACT

An imaging device comprising a linear array of laser diodes that are adapted to provide an optical output comprising a plurality of spaced-apart optical beams. Focusing optics are configured to form a plurality of image points from said spaced-apart optical beams, the image points being spaced apart along a first axis. The image points have a non-uniform spacing along the first axis. By scanning the linear array along a photosensitive plate, and timing the firing of lasers accordingly, every pixel point on the photosensitive plate can be imaged by one of the image points from the laser array. Non-uniform spacing of the image points can provide advantages in heat dissipation from the laser elements, and reduction of some printing artifacts on the photosensitive plate.

The present invention relates to the use of semiconductor laser arrays for use in printing and imaging applications.

The use of arrays of semiconductor lasers is becoming increasingly popular in a large number of applications, including thermal printing, computer-to-plate printing, computed radiography, to mention but a few. Monolithic arrays of semiconductor lasers are preferred because the lasers are aligned with high precision using lithographic techniques rather than by mechanical positioning of individual lasers, fibre pigtails or optical components.

Arrays of individually addressable semiconductor lasers have been reported since at least 1982. In Applied Physics Letters, Vol 41, pp 1040-1042 (1982), Botez et al report an array of monolithic semiconductor lasers suitable for use in optical recording. In Applied Optics, Vol 23, pp 4613-4619 (1984), Carlin et al describe the use of such an array to store multiple tracks of data on a recordable optical disk.

Interleaved scanning using a monolithic laser array has been reported for computer to plate (CtP) printing where a flat or curved plate is exposed (U.S. Pat. No. 6,603,496 and U.S. Pat. No. 6,784,912). In U.S. Pat. No. 6,784,912 the plate is mounted on a rotating drum and the laser array is scanned across the drum as it rotates so the imaged dots scan in a helical pattern. Laser array print heads can be used to image a variety of plates including flexographic relief plates and plates for offset printing. Laser arrays could also be used to expose drums or plates for gravure printing. They have also been used in electrographic presses. WO 98/47037 describes an electronic printer in which a laser array is utilised to expose a photosensitive plate in which the plate is mounted on a rotating drum and the beams are moved across the drum using a plurality of multi-faceted polygon disks, mounted for common rotation on an axis, a plurality of data modulated beams, wherein each of the beams is configured to impinge on the facets of one of the disks and be reflected therefrom toward the surface of the drum.

U.S. Pat. No. 6,784,912 describes the use of a laser array having an array of n laser diodes to image n image points so that one laser diode of the array is allocated to each i-th point, with i being from 1 to n. The n image points are separated by a constant spatial interval / between adjacent image points, with a pitch distance p of dots to be imaged by the array. The laser diodes are individually-drivable single stripe laser diodes.

In U.S. Pat. No. 6,784,192 the spatial interval/between adjacent image points, measured in units of the pitch distance p of the dots, is an integral multiple m of the pitch distance p between the dots. In this device, the integral multiple m and the number n of image points have no common divisor; they are again integers with no prime factors in common. Moreover, it is made clear that a necessary condition is that the n image points have a constant spatial interval /. The scanning method involves the steps of simultaneously generating n image points on a printing plate by a plurality of laser light sources, generating a relative motion between the image points and printing plate, displacing the image points with a translation component perpendicular to the line of the image points by a first specific amount, displacing the n image points in a direction defined by the line of the n image points by a second specific amount, repeating the displacement steps, an amount of the second specific displacement being greater than the spatial interval / of adjacent image points.

U.S. Pat. No. 4,069,486 describes the placement of nozzles in an ink-jet printer for reproducing a scanned image. Using a single array comprising N nozzles spaced k resolution elements apart along an array axis, the criteria for interlacing are as follows, where N and k are both integers:

1. The nozzle array is advanced N resolution elements in the axial direction for every single revolution of the print cylinder
2. If k is factorised into prime factors such that k=A×B×. . . ×M, N must be an integer which has no prime factors in common with k, i.e. the fraction k/N must be irreducible.

U.S. Pat. No. 4,401,991 describes an ink jet printing system that makes use of interleaved scanning. The print head has a single array of Nt nozzles that are uniformly spaced. The method comprises the steps of passing the ink jet print head repeatedly across the print media and translating the ink jet print head a distance corresponding to the product between the number of nozzles and the spacing between adjacent nozzles, computed in pixels. Then, the print data are processed for printing on print lines one pixel spacing apart, and a pseudo pixel spacing is assigned, such spacing corresponding to k′ pseudo pixels between nozzles on the respective array. According to U.S. 4,401,991, k′ is an integer having no common factor with the number of nozzles.

U.S. Pat. No. 5,300,956 describes the use of interleaved scanning for this configuration using a multibeam semiconductor laser array. The array includes n independently drivable semiconductor laser elements which are arranged with a distance r between the elements in such a manner that light of centres of respective laser beams emitted from the semiconductor laser elements are aligned on a straight line.

### SUMMARY OF THE INVENTION

According to the present invention, it has been discovered that the use of non-uniform spacing of optical outputs of the laser array can have significant advantages.

According to one aspect, the present invention provides a device for imaging comprising:
a linear array of laser diodes adapted to provide an optical output comprising a plurality of spaced-apart optical beams;
focusing optics adapted to form a plurality of image points from said spaced-apart optical beams, the image points being spaced apart along a first axis, the image points having a non-uniform spacing along the first axis. The expression ‘linear array’ is intended to encompass an array in which the laser diodes and/or image points are disposed in an array along the first axis, the first axis being at least transverse to, and preferably orthogonal to, the axis of the optical beams. The expression ‘image points’ is intended to encompass beam cross-sections at an image plane some distance downstream from the imaging optics where the beams would ordinarily reach a suitable imaging medium such as a photosensitive plate. The expression ‘pixel points’ is intended to encompass spatially resolvable elements on the photosensitive medium using the image points.

In one preferred embodiment, the pixel points are arranged on a rectangular grid of pitch w, one axis of the grid being parallel to the first axis, the spacing of each pair of adjacent image points along the first axis being an integer multiple of the pitch w.

In another arrangement, each image point generates a pixel point of pitch w, along the first axis, the spacing of each pair of adjacent image points along the first axis being an integer multiple of the pitch w.

The pitch w is, in preferred arrangements, the distance parallel to the first axis which the laser array must be moved relative to the photosensitive medium in order to create two adjacent pixel points on the photosensitive using the same laser diode in the array.

In another arrangement, the non-uniform spacing defines an increasing density of image points towards at least one end of the linear array. In another arrangement the non-uniform spacing defines an increasing density of image points towards both ends of the linear array. In another arrangement, the non-uniform spacing defines a decreasing density of image points towards the centre of the linear array.

In another arrangement, each image point generates a pixel point of pitch w, along the first axis, the spacing of each pair of adjacent image points along the first axis being a non-integer multiple of the pitch w.

The image points may be arranged along the first axis spaced in groups, the spacing between the intra-group image points being less than the spacing between inter-group image points. Each group may comprise only two image points, or more than two image points.

According to another aspect, the present invention provides a semiconductor laser array comprising a plurality of individually addressable laser elements together defining a plurality of optical outputs disposed in a linear array, the laser elements and optical outputs therefrom being spaced in groups, the spacing between the intra-group laser elements being less than the spacing between inter-group laser elements.

Each group may comprise only two laser elements, or more than two laser elements.

Each laser element may include a bond pad for electrical connection to the laser element, each group of two laser elements having:
a first bond pad extending laterally from the first laser element in the group in a direction away from the second laser element in the group, and
a second bond pad extending laterally from the second laser element in the group in a direction away from the first laser element in the group.

The first and second bond pads may extend in a lateral direction over more than half of the inter-group spacing distance.

The device for imaging may form N image points spaced apart along the first axis, and further include: drive means adapted to displace the optical beams, relative to a photosensitive substrate, along the first axis, so as to enable imaging of a row of pixels on the photosensitive substrate along the first axis, by selective firing of the lasers, the drive means defining m firing positions within each length of the N image points along the first axis, the firing positions together yielding pixels on the photosensitive substrate of pitch P, the position xᵢ, measured along the first axis of the i-th image point being given by xᵢ=(i−1)m+kᵢN, wherein kᵢ is an integer and for all x there are at least two different values of k. The m firing positions may each be separated by a number of pixels equal to the number of image points N in the array. The values of k may be chosen so that every pixel along the first axis is imaged no more than once, by selection of one of the image points in one of the firing positions.

According to another aspect, the present invention provides a semiconductor laser array comprising a plurality of individually addressable laser elements together defining a plurality of optical outputs disposed in a linear array, the optical outputs being spaced in the linear array according to a predetermined function such that the inter-element spacing along the array varies as a monotonically increasing function or a monotonically decreasing function.

Multiple linear arrays may be arranged one over another to form two dimensional arrays.

### BRIEF DESCRIPTION OF THE DRAWINGS

Embodiments of the present invention will now be described by way of example and with reference to the accompanying drawings in which:

FIG. 1 shows a schematic diagram of an apparatus for imaging a printing plate on a cylinder, using an imaging head that includes a laser array;

FIG. 2 shows a schematic plan view of a laser array in which the laser elements are arranged to have non-uniform spacing;

FIG. 3 shows a schematic plan view of a laser array in which the laser elements are arranged to have non-uniform spacing, with spacing being less towards the edges of the array;

FIG. 4 shows a schematic plan view of a laser array in which the laser elements are arranged to have non-uniform spacing, with spacing being less towards the centre of the array;

FIG. 5 shows a schematic plan view of a laser array in which the laser elements are grouped in pairs;

FIG. 6 shows a raster scan pattern for printing a plurality of pixel points on a photosensitive medium using an array of laser beams having non-constant pitch;

FIG. 7 shows a raster scan pattern for printing a plurality of pixel points on a photosensitive medium using an array of laser beams having non-constant pitch; and

FIG. 8 shows a schematic perspective view of apparatus for scanning a plurality of laser beams across the surface of a rotating cylinder.

### DESCRIPTION OF PREFERRED EMBODIMENTS

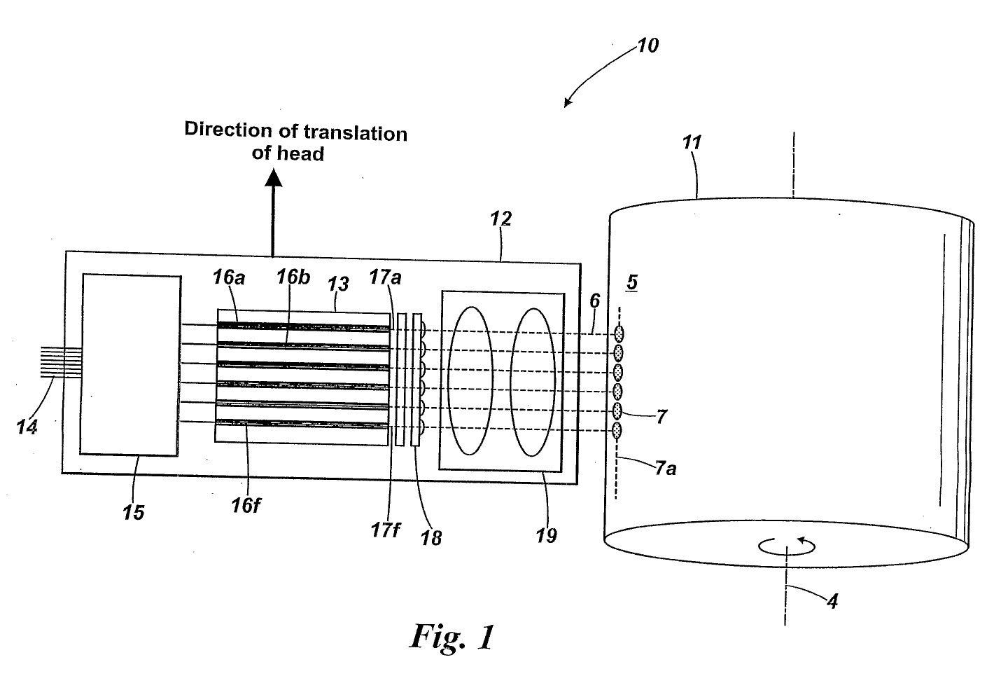

With reference to FIG. 1, there is shown a schematic representation of a system 10 for imaging a printing plate surface 5 that is disposed on a cylinder 11, comprising an imaging head 12 that includes a laser array 13. An image is first processed into electronic data which are delivered along with control data to the imaging head 12 via a data and control interface 14. Drive electronics 15 further processes the data and applies individual drive currents to laser elements 16a, 16b, . . . 16f of the laser array 13. The laser array 13 produces an array of N parallel beams 17a, 17b, . . . 17f. Imaging optics 18, 19 are used to project the N laser beams 6 onto the plate 5, the output of each laser element 16 being imaged to a unique point 7 on the printing plate.

In a preferred arrangement the laser beams 6 or 17 can be monitored, for example by means of a photodiode or an array of photodiodes (not shown), to provide feedback to the drive electronics 15. In a preferred arrangement the laser elements 16a-16f are all individually addressable. In a preferred arrangement, the imaging optics may comprise both micro-optics 18 and bulk optics 19, which together can be used to modify the diameters of the beams 6, in directions orthogonal and/or parallel to an axis 7a defined by the row of image points 7. The imaging optics 18, 19 may also be configured to adjust the spatial interval or pitch of the beams along the axis 7a. In a preferred arrangement, the magnification of the bulk optics 19 is M.

The entire plate 5 is scanned by a combination of the rotation of the cylinder 11 and lateral movement of the imaging head 12 in a direction parallel to the axis 7a of the image points. Thus, in a general aspect, the apparatus includes a drive mechanism adapted to displace the optical beams 6, relative to a photosensitive medium (e.g. disposed on the printing plate surface 5), along the axis of the image points and preferably also transverse to the axis of the image points. The number of laser elements in the array can be varied according to requirements.

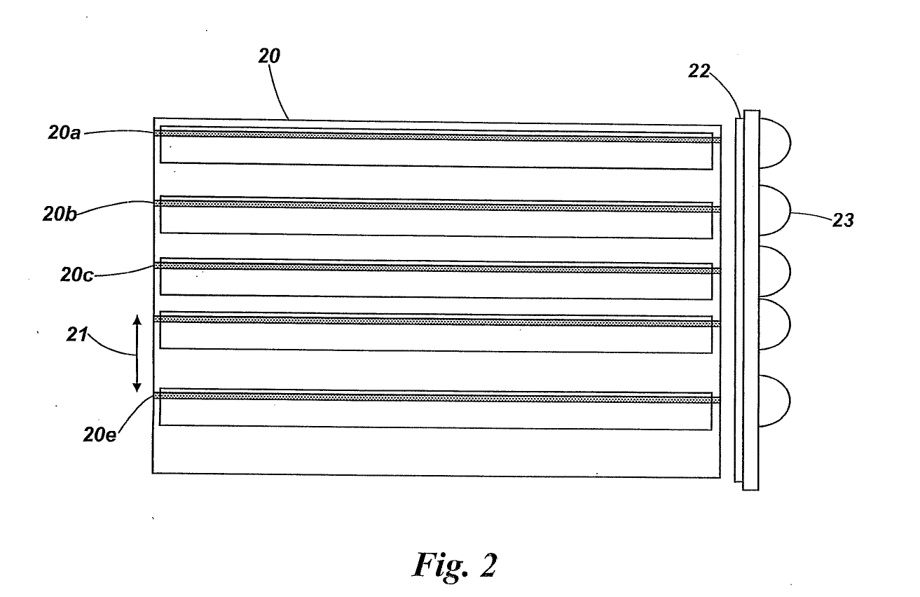

FIG. 2 shows a laser array 20 in which the individual laser elements 20a, 20b, . . . 20e are arranged with a non-uniform pitch 21, i.e. the inter-element spacing is not uniform across all laser elements 20a-20e. Throughout the present specification, the expression “spacing” or “pitch” refers to a “peak-to-peak” distance transverse (and preferably orthogonal) to the axis of the laser beams or a “centre-to-centre” distance transverse (preferably orthogonal) to the laser axes.

It is assumed that the overall magnification of the system is M, which is determined by the geometry of the system and the specification of the bulk optics 19 shown in FIG. 1. In many systems, M will be equal to 1. The optical head includes the micro-optical element 22 (or ‘FAG’, fast axis collimator) for collimating the fast axis of each laser element 20a, 20b, . . . 20f which is preferably a single cylindrical lens running across the full width of the array. In the example of FIG. 1, the expression “fast axis” refers to the axis orthogonal to the axis 7a defined by the row of image points 7, so called because the printing plate passes across the laser beams 6 by virtue of rotation of the cylinder 11 faster than by virtue of translation of the laser array parallel to the axis 7a. The optical head includes the micro-optical elements 23 (or ‘SAC’, slow axis collimator) which is an array of lenses which collimate the slow axis of each laser individually. Preferably each laser element has a corresponding slow axis lens 23. The FAC and SAC elements 22, 23 may be composed of multiple elements, or may not be required at all. Together with the bulk optics 19, the micro-optical elements 22, 23 can be used to determine the size of the image points on the photosensitive medium on the printing plate. The image points can have different diameters parallel and orthogonal to the fast axis.

It will be appreciated that complex optical elements 18, 19 can be used to alter the spacing between image points 7. However, in the preferred embodiments, the optical system has a constant magnification across the entire width of the array, so a laser array of width A is imaged to a width MA on the photosensitive medium.

In FIG. 2, the spacing 21 of elements of the array is an integral number of w/M, so the separation of image points is always an integral number of w, where w is the pitch of pixel points that must be addressable on the photosensitive medium. Furthermore, the system is aligned so that each of the image points lies within a pixel point. Because the pitch or spacing of the laser elements 16a-16f is not constant, when the imaging head is rastered across the plate the lasers can be used in a ‘pseudo-random’ or other pre-selected order, i.e. mixing the order in which the lasers are used. By introducing randomness or specially selected order into the way in which lasers are used, undesirable image artefacts such as banding and image beating effects can be reduced substantially, as will be discussed later.

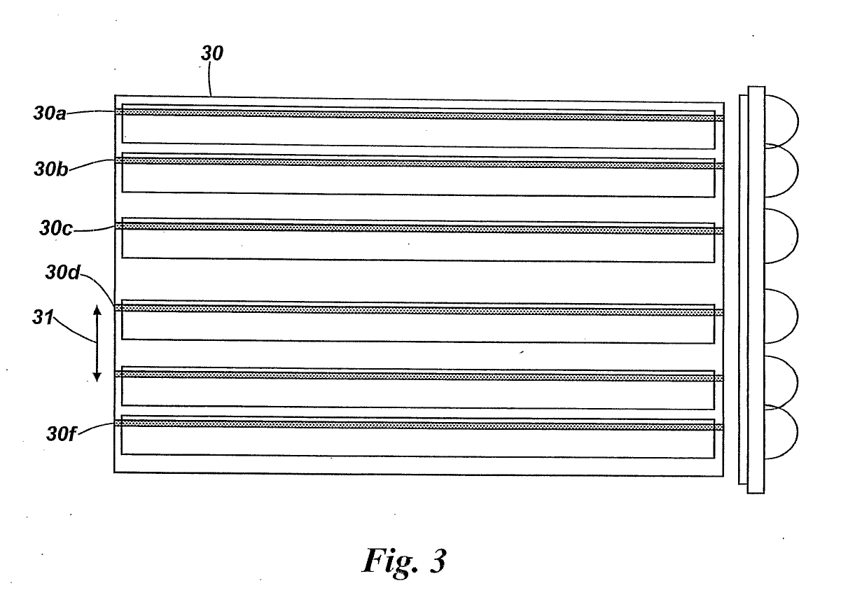

FIG. 3 shows a laser array 30 in which the individual laser elements 30a, 30b, . . . 30f are arranged with a non-uniform pitch 31, i.e. the inter-element spacing is not uniform. The array 30 illustrated in FIG. 3 is similar to that of FIG. 2, in that the separation between elements of the array is an integral number of w/M, but in this case the laser elements 30 are clustered together in preferred locations. In FIG. 3 the lasers are clustered closer together towards the sides of the laser array or bar. In other words, laser elements 30a and 30b are closer together than are laser arrays 30c and 30d, for example. It has been found that the temperature rise when the lasers are operated is smaller towards the sides of the bar. By increasing the density of elements at the sides, the temperature rise across the laser array can be made more uniform, reducing thermal crosstalk between lasers elements and enabling each laser to deliver a more constant power. The reduced thermal crosstalk will further reduce banding and image beating effects on the photosensitive medium. This ability to accommodate a higher density of laser element towards the sides of the laser array provides a useful synergy with the requirement to provide varying laser element spacing.

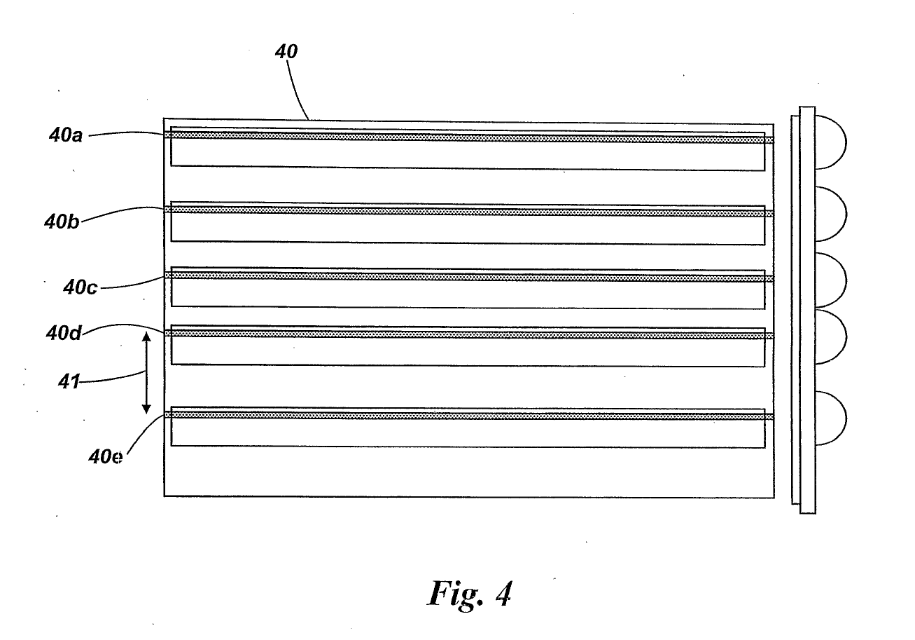

FIG. 4 shows a laser array 40 in which the individual laser elements 40a, 40b, . . . 40e are arranged with a non-uniform pitch 41, i.e. the inter-element spacing is not uniform.

In FIG. 4, the separation between laser elements 40a-40e is no longer an integral number of w/M. However, it is still necessary to align image points 7 onto pixel points and in this embodiment timing of the firing of laser elements is used to achieve this. As the cylinder 11 rotates and the imaging head is translated along axis 7a, electronic timing will allow every image point to be brought into coincidence with its corresponding pixel point. In this approach, the order in which laser elements are used is partially randomised compared to an array of constant pitch, and the electronic timing is also partially randomised, reducing power supply fluctuations and reducing beating effects with mechanical variations, such as those that arise for rotation of the cylinder. This timing concept can also be used to compensate for incorrect positioning of dots on the printing plate 5 resulting from manufacturing tolerances and aberrations in the optics that result in lateral displacement from the ideal dot position. A disadvantage of this approach is that the number of lasers that can be used simultaneously is restricted to those that are in alignment with the pixel points at a particular instant in time. However, this approach can be advantageously used when the array of beams is moved in a meander path.

In other arrangements (not shown), the inter-element spacing along the array may vary as monotonically increasing function or a monotonically decreasing function.

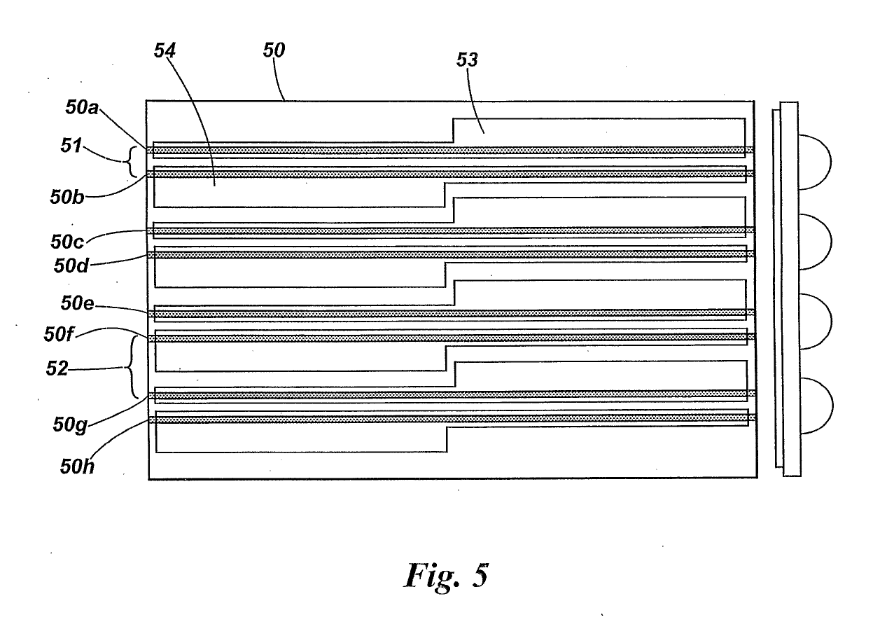

FIG. 5 shows a laser array 50 in which the individual laser elements 50a, 50b, . . . 50h are arranged with a non-uniform pitch 51, 52 i.e. the inter-element spacing is not uniform. FIG. 5 shows an array in which the lasers are located in groups such that there are at least two different values for laser element spacing. In FIG. 5, the laser elements 50 are grouped in pairs, with the spacing between the lasers in each pair being p and the centre-to-centre spacing between corresponding elements in adjacent pairs being P. Alternatively, it can be seen that the intra-group spacing 51 (e.g. between laser elements 50a and 50b) has a first value and the inter-group spacing 52 (e.g. between laser elements 50f and 50g) has a second value.

This approach retains many of the benefits of a using constant pitch but that the number of lasers can be doubled for only a small increase in the width of chip used to form the array, or alternatively the width of the chip can be nearly halved for the same number of lasers. Reducing the width of the chip has the benefits of reducing the effect of optical aberrations, particularly in the bulk lens 19, lowering the cost and complexity and offering improved better optical performance. The pitch P between laser pairs can also be made non-constant bringing the advantages noted in the embodiments above.

The width of the array can be reduced by virtue of disposing the bond pads 53 and 54 used for electrical connection to the drive electrodes of the laser elements on laterally opposite sides to one another on adjacent laser elements (e.g. 50a, 50b) within a group.

Another objective of the present invention is to overcome certain limitations associated with imaging using laser arrays, in particular banding in the image.

In a preferred CtP system, the plate 5 is mounted on a cylinder 11 which can be rotated about the axis 4 which passes through the centre of the cylinder (FIG. 1). The beams 6 from the imaging head laser array 13 are projected onto the cylinder, to form the series of image points 7. The plate surface 5 can be divided into a rectangular grid of pixel points, with one axis of the grid parallel to the axis of rotation of the cylinder and the other axis of the grid corresponding to a circumference of the cylinder. The boundaries of each rectangle within this grid define a pixel point. In order to expose the plate correctly, the image points 7 need to be systematically aligned with pixel points. In a preferred embodiment, the image points 7 can be brought into alignment with pixel points by a combination of rotating the cylinder 11 about its axis 4 and translating the imaging head 12 parallel to the axis 4 of rotation of the cylinder. By correctly timing the drive signal to an individual laser element 16, every pixel on the plate can be exposed.

The pixels usually have sides of equal length, i.e. the grid pixel is a square grid, although this need not be the case. The image point 7 may have unequal lengths parallel and perpendicular to the axis of rotation of the cylinder, and the length in the perpendicular (or circumferential) direction is usually the shorter length. The length of the image point in the direction parallel to the cylinder axis is usually similar to the pitch of the grid of pixel points.

In a preferred embodiment the speed of rotation of the cylinder 11 and the translation speed of the imaging head 12 parallel to the axis 7a are constant during plate exposure. Algorithms can be developed to process the image into digital data streams, with each stream being used to modulate the output of the appropriate laser in the array.

Preferred algorithms have the property that all pixel points on the plate are imaged exactly once, and that all the lasers can be utilised simultaneously.

An aspect of the invention is to provide interleaving raster scan methods that can be implemented using arrays of non-constant pitch as described in connection with FIGS. 1 to 5.

In a preferred embodiment: the array of beams has a non-constant pitch; the array of beams is advanced N pixel elements in the axial direction for every single revolution of the print cylinder (where N is the number of beams in the array); every pixel point is imaged once within a main field of a raster scan; and no pixel point is imaged more than once.

The laser array produces N laser beams, and a continuous line of adjacent pixels can be imaged (other than the edge regions of the raster scan) after m scans (a scan being a combination of a firing of the relevant lasers in the array and an indexing of the array to a new firing position in the axial direction of the row of image points 7). If m is factorised into prime factors such that m=A×B×. . . ×M, N must be an integer which has no prime factors in common with m, i.e. the fraction m/N must be irreducible, in order to avoid wasted alignment of laser elements in the array with pixel positions that have already been accessed in a previous scan.

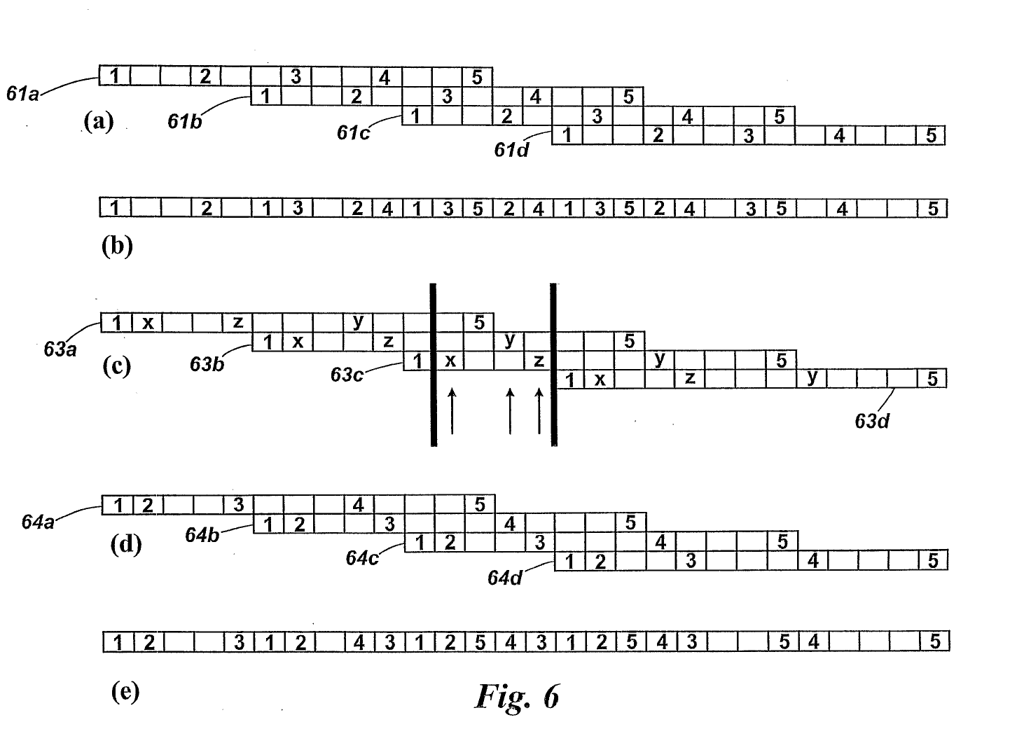

FIG. 6 illustrates how to develop an array that has these properties for the case N=5.

FIG. 6(a) illustrates the case for an array of 5 beams with a constant pitch m=3 between imaged pixels (this reproduces the example cited in U.S. Pat. No. 6,784,192). The array of N=5 elements is intended to form a continuous line after m=3 scans. The four rows 61a, 61b, 61c, 61d in FIG. 6(a) each indicate the points imaged by lasers 1, 2, . . . , 5 in a single line after each of 4 imaging cycles, the first (top row) corresponding to the first scan, the second row to the second scan etc. FIG. 6(b) shows the resulting line of exposed pixels, and it can be seen the pattern 1, 3, 5, 2, 4 repeats in the region where the pixels are completely inscribed (away from the edge regions).

To visualise an array of non-constant pitch, we start by considering the positions of the image points from the first (laser 1) and last (laser N) elements of the laser array to be fixed (although this not a requirement as will be seen later), and separated by a number of pixels equal to m(N−1), i.e. the centre-to-centre distance for each image point being m(N−1) pixels. It is then necessary to determine the positions of the remaining image points. FIG. 6(c) illustrates a graphical technique for assigning positions to lasers 2, 3, and 4 again for the case N=5 and m=3, where m still represents the number of scans to completely inscribe the pixels.

Every pixel should have been imaged after m scans of the cylinder, in this case three scans, and the top three lines 63a, 63b, 63c of FIG. 6(c) show the positions imaged by lasers 1 and 5 during the corresponding first three scans. Now consider the pixel points between the bold lines. In order to image every point, one beam image point needs to be present in each of the three columns marked by arrows and within the boundaries of the array defined by the bold lines. This requirement can be fulfilled by the three points x, y, and z. However, there are no unique positions for each of the three beam imaging points—it is simply sufficient that there is a single laser image in each of the columns within the array boundaries. Having chosen the points x, y, and z within the bold lines, they are then replicated in the corresponding positions in the other rows of the Figure.

The resulting array of imaged points is illustrated in the top row 64a of FIG. 6(d), where it can be seen the imaged points are no longer separated by a constant pitch. The remaining rows 64b, 64c, 64d show the imaged points after successive scans and it can be verified that, in the main field of the raster scan, i.e. other than in the edge areas to the left and right, every pixel is imaged exactly once. The main field of the raster scan will always extend to within one array width of the edge of the horizontal scan, i.e. the scan in the axial direction of the image points. It will be understood that in normal use, the edges of an axial scan will not cause a problem as these can be arranged to be outside of the normal “print” area and the laser array is not fired until the relevant laser element is in position for the main field.

FIG. 6(e) shows the resulting line of exposed pixels, where it can be seen the repeating pattern is 1, 2, 5, 4, 3. It is therefore possible to change the order in which beams image adjacent image points.

It will be appreciated that in the general case, the positions of the image points can be chosen by starting from the case of a constant pitch and then translating individual beams by an amount equal to kN, where k is an integer. It will also be appreciated that the case of constant pitch is a special case.

In the general case of an array of N beams, the position xᵢ of the i-th beam measured in pixel points is given by

x₁=0+k₁N

x_{N}=m(N−1)+k_{N}N and

xᵢ=(i−1)m+kᵢN, where 1≦i≦N and kᵢ is an integer.

For an array of constant pitch, 0≦ᵢ≦m(N−1) and all the values kᵢ are zero or all the values of kᵢ are the same integer value. Thus, for the example where N=5 and m=3, the values for k₁=k₂=k₃=k₄=k₅=0 will yield laser positions x₁, x₂, x₃, x₄, x₅=0, 3, 6, 9, 12 respectively, exactly as shown in FIG. 6(a). Similarly, where all k₁ to k₅=1, this will yield laser positions 5, 8, 11, 14, 17. It will be understood that this produces the same array configuration, as it is the positions relative to the first (or last) laser in the array that are being determined.

For non-uniform spacing of beams and image points, there will be at least two different values of kᵢ for any given array. By choosing appropriate different values of kᵢ it is possible to design arrays that are more compact or that are wider than for the case of equally spaced elements. Compact arrays offer the advantage that the width of the array of beams is reduced. If a monolithic array of semiconductor lasers is used, together with micro and bulk optics, to generate the beams, the width of the semiconductor chip can be made smaller. Imaging a smaller array means that lenses of reduced diameter can be used, or, for the optical elements, aberrations will be reduced. In contrast, wider arrays allow the average separation between lasers to be increased, allowing the lasers to be run at a higher power.

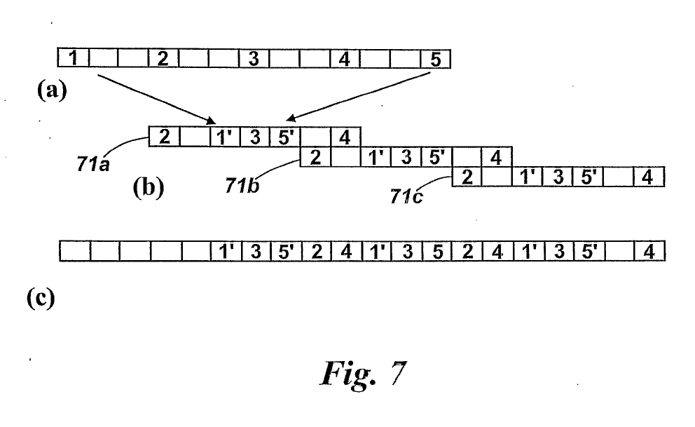

FIG. 7 illustrates a compact array for N=5 and m=3. FIG. 7(a) shows the corresponding array of constant pitch. The top row 71a of FIG. 7(b) shows the positions of the beams with beam 1 moved 5 positions to the right to 1′, and beam 5 translated 5 positions to the left to position 5′. The remaining rows 71b, 71c show the pixels imaged after a further two rotations of the cylinder, and FIG. 7(c) shows the resulting line of imaged pixels.

Because there are not, in general, unique values of kᵢ it is possible to introduce redundancy into the array of beams. This means it is possible to write different rows on the plate using different combinations of beams. For example, sequential rows could be written with different beam combinations, introducing randomness into the way sequential rows are written and breaking up the periodic use of individual beams that gives rise to effects such as banding. It will be appreciated that is also possible to change the lasers within the same row, provided care is taken to ensure all pixels are imaged exactly once.

Further, it has been discovered that imaging optics 18, 19 such as that indicated in FIG. 1 can sometimes introduce a systematic variation in image point 7 positions relative to a perfect regularly spaced grid. In other words, while the optics may be set up such that the first and last laser elements 16a, 16f in the array might produce perfectly positioned points 7, there may be deviation from regular spacing of points 7 from intermediate laser elements 16b . . . 16e as a result of aberrations in the optics. These aberrations can result in gradually changing positive and negative displacement from perfect positioning of image points 7 from successive laser elements in the array. Because the choice of values of k allows the user to select the order in which laser elements are selected in the formation of rows 71a . . . 71c etc, it is possible to minimise the effects of visible banding by ensuring that a laser element 16 that produces a point 7 having a large positive displacement from true grid position and a laser element 16 that produces a point 7 having a large negative displacement from true grid position are not fired to produce adjacent pixels, such as y and z in FIG. 6(c).

Groups of lasers where the separation within a group is one pixel are special cases of arrays with a non-constant pitch. In a preferred embodiment, the spacing between beams within a group is exactly one pixel, there are n beams within a group and N groups within the array. The total number of beams is therefore nN.

The positions of the beams within the array are then given by:

xᵢⱼ=(i−1)nm+KᵢnN+j−1

where 1≦i≦N, 1≦n≦m and kᵢ is an integer

Various modifications may be made to the exemplary systems described. For continuous imaging, the printing plate 5 is mounted on the cylinder 11 and the cylinder together with the printing plate is rotated about its axis 4 as indicated in FIG. 1. At the same time, the imaging head 12 may be translated along an axis parallel to the axis 7a of the image points 7. The translation velocity may be determined by the number N of laser beams 6 and the width of an image point or pixel point. The result is that an individual beam 6 inscribes a helical imaging path on the plate 5 which encircles the cylinder axis 4. For step-wise imaging, a similar imaging path may be used but the cylinder and/or imaging head indexed in step-wise increments along their required paths.

Other image paths can be used. For example the image points 7 can be moved along a line parallel to the cylinder axis 4 until a complete line has been imaged and then the cylinder 11 can be rotated about the axis 4 by one or more pixels and the process repeated until the page has been completely imaged (which may involve one or more complete revolutions of the cylinder). The image points therefore inscribe a meander path on the page.

Alternatively, the imaging head 12 can be maintained in a fixed position while the cylinder 11 is rotated through a complete revolution, in which case individual laser elements 16a-16f will inscribe a circumferential path on the plate 5. The image points 7 can then be translated by one or more pixels and the process repeated.

All of the foregoing techniques and many others where the rotational and translational movements are continuous or step-by-step can be devised. It is, however, particularly preferred to use imaging schemes where: the array of beams has a non-constant pitch; the cylinder is rotated so as to advance a point on the surface N pixel elements in the circumferential direction for every single scan of the image points; every pixel point is imaged once within a main field of a raster scan; and no pixel point is imaged more than once.

In preferred arrangements, the line of image points 7 is parallel to the axis 4 of rotation of the cylinder 11. However, it is also possible for the line of image points 7 to be tilted so as to reduce the separation between imaged lines of pixels.

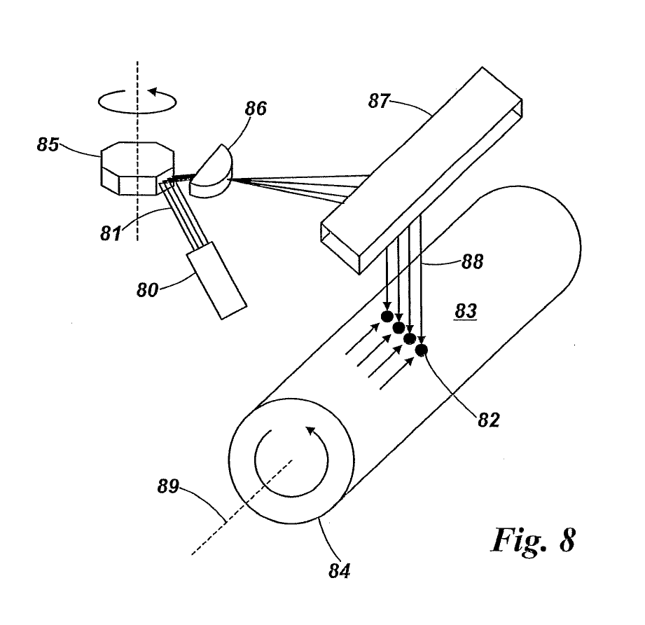

Although these embodiments have been described for a CtP system where the cylinder rotates at a relatively high speed and the array of beams is translated at a slow constant speed parallel to the line of beams and parallel to the axis of rotation of the cylinder, the same techniques can be applied to systems such as electrophotographic presses and printers (also known as laser printers) where the cylinder rotates at a relatively low speed and the array of beams is translated at a high constant speed perpendicular to the line of beams but still parallel to the axis of rotation of the cylinder as shown in FIG. 8.

FIG. 8 shows a laser module 80 which produces N laser beams 81 which are projected onto N image points 82 on a photosensitive receptor on the surface 83 of a cylinder 84. In FIG. 8, the laser module 80 may comprise similar elements to the imaging head of FIG. 1, namely an array of N individually addressable lasers and a first optical system comprising micro- and bulk optics. Other means can be used to create the beams. The beams 81 from the laser module 80 are incident on a rotary polyhedral mirror 85, often called a polygon scanner, and the beams reflected from the rotary polyhedral mirror pass through a second optical system 86, 87 comprising refractive, reflective and diffractive elements such as lenses and mirrors. The beams 88 are then directed onto the surface of a charged photoreceptor which is moving at a constant speed. Rotation of the rotary polyhedral mirror 85 causes the laser beams 88 to scan in a direction parallel to the axis 89 of the cylinder 84. Since each of the laser beams is modulated according to the image to be output, an electrostatic latent image is formed on the photoreceptor and the electrostatic latent image is developed to provide a visible toner image. Non-constant pitch of the laser elements in laser module 80 is possible in this arrangement.

Other embodiments are intentionally within the scope of the accompanying claims.

1. A device for imaging comprising:
a linear array of laser diodes adapted to provide an optical output comprising a plurality of spaced-apart optical beams;
focusing optics adapted to form a plurality of image points from said spaced-apart optical beams, the image points being spaced apart along a first axis, the image points having a non-uniform spacing along the first axis.

2. The device of claim 1 in which each image point generates a pixel point of pitch w, along the first axis, the spacing of each pair of adjacent image points along the first axis being an integer multiple of the pitch w.

3. The device of claim 1 in which the non-uniform spacing defines an increasing density of image points towards at least one end of the linear array.

4. The device of claim 3 in which the non-uniform spacing defines an increasing density of image points towards both ends of the linear array.

5. The device of claim 3 in which the non-uniform spacing defines a decreasing density of image points towards the centre of the linear array.

6. The device of claim 1 in which each image point generates a pixel point of pitch w, along the first axis, the spacing of each pair of adjacent image points along the first axis being a non-integer multiple of the pitch w.

7. The device of claim 1 in which the image points are arranged along the first axis spaced in groups, the spacing between the intra-group image points being less than the spacing between inter-group image points.

8. The device of claim 6 in which each groups comprises only two image points.

9. A semiconductor laser array comprising a plurality of individually addressable laser elements together defining a plurality of optical outputs disposed in a linear array, the laser elements and optical outputs therefrom being spaced in groups, the spacing between the intra-group laser elements being less than the spacing between inter-group laser elements.

10. The laser array of claim 9 in which each group comprises only two laser elements.

11. The laser array or claim 9 in which each laser element includes a bond pad for electrical connection to the laser element, each group of two laser elements having:
a first bond pad extending laterally from the first laser element in the group in a direction away from the second laser element in the group, and
a second bond pad extending laterally from the second laser element in the group in a direction away from the first laser element in the group.

12. The laser array of claim 11 in which the first and second bond pads extend in a lateral direction over more than half of the inter-group spacing distance.

13. The device of claim 1 adapted to form N image points spaced apart along the first axis, and further including:
drive means adapted to displace the optical beams, relative to a photosensitive substrate, along the first axis, so as to enable imaging of a row of pixels on the photosensitive substrate along the first axis, by selective firing of the lasers,
the drive means defining m firing positions within each length of the N image points along the first axis, the firing positions together yielding pixels on the photosensitive substrate of pitch P,
the position xᵢ measured along the first axis of the i-th image point being given by xᵢ=(i−1)m+kᵢN, wherein kᵢ is an integer and for all x there are at least two different values of k.

14. The device of claim 13 in which the m firing positions are each separated by a number of pixels equal to the number of image points N in the array.

15. The device of claim 13 in which the values of k are chosen so that every pixel along the first axis is imaged no more than once, by selection of one of the image points in one of the firing positions.

16. The device of claim 13 having a linear array of laser diodes adapted to selectively form more than N image points spaced apart along the first axis, and further including control means for selectively firing lasers when at the firing positions, the control means adapted to ensure only one of several groups of N lasers is active at any one time for firing, each different group having image points with positions x as defined.

17. The device of claim 16 further including drive means adapted to displace the optical beams, relative to a photosensitive substrate, along a second axis in a direction substantially orthogonal to the first axis, so as to enable imaging of a grid of pixels on the photosensitive substrate extending both along the first axis and the second axis, by selective firing of the lasers, the control means adapted to select different ones of the groups of lasers for different pixel rows along the second axis.

18. A semiconductor laser array comprising a plurality of individually addressable laser elements together defining a plurality of optical outputs disposed in a linear array, the optical outputs being spaced in the linear array according to a predetermined function such that the inter-element spacing along the array varies as a monotonically increasing function or a monotonically decreasing function.
